(19) United States
(12) Patent Application Publication
(10) Pub. No.: US 2025/0212534 A1
(43) Pub. Date: Jun. 26, 2025

(54) CONTACT PAD PROCESSING METHOD

(71) Applicant: STMicroelectronics International N.V., Geneva (CH)

(72) Inventors: Pierre BAR, Grenoble (FR); Guillaume CLAVEAU, Grenoble (FR); Etienne MORTINI, Les Adrets (FR)

(73) Assignee: STMicroelectronics International N.V., Geneva (CH)

(21) Appl. No.: 18/977,651

(22) Filed: Dec. 11, 2024

(30) Foreign Application Priority Data
Dec. 26, 2023 (FR) 2315298

(51) Int. Cl. H10F 39/00; H10F 39/18

(52) U.S. Cl. CPC H10F 39/028; H10F 39/014; H10F 39/024; H10F 39/18; H10F 39/804; H10F 39/8063; H10F 39/811

(57) ABSTRACT

The present description concerns an electronic circuit manufacturing method comprising, in the order, forming an opening in a semiconductor substrate, the semiconductor substrate including a first surface and a second surface opposite to the first surface, the opening positioned between the first surface and the second surface and forming an electrically-conductive pad, the electrically-conductive pad including a first portion positioned over the first surface and a second portion covering the flanks of the opening and delimiting a gap in the opening, and depositing a first layer covering the electrically-conductive pad and filling the gap, the first layer containing a first resin, the first resin being non-photosensitive, and crosslinking the first resin in the first layer, and chemically etching by plasma the first layer to delimit a first block of the first resin in the gap, and depositing a first protection layer on the first block.

### CROSS-REFERENCE TO RELATED APPLICATION

This application is a translation of and claims the priority benefit of French patent application number 23/15298, filed on 26 Dec. 2023, entitled “Procédé de traitement de plots de reprise de contact”, which is hereby incorporated by reference to the maximum extent allowable by law.

### BACKGROUND

### Technical Field

The present disclosure generally concerns the field of electronic circuits, in particular of image sensors, comprising contact pads, and more particularly aims at a method of manufacturing an image sensor.

### Description of the Related Art

An image sensor generally comprises a plurality of photodetectors, for example photodiodes, integrated inside and on top of a semiconductor substrate. The photodetectors may be topped by a layer of microlenses. This microlens layer enables to focus the incident radiation onto the photodetectors. An image sensor further comprises contact pads which extend over a side of the substrate and through the semiconductor substrate, particularly when the image sensor is intended to be illuminated from this side. Such contact pads result in the presence of significant raised areas which may in particular interfere with the manufacturing steps which follow the forming of the contact pads, and in particular the forming of the microlens layer.

It would be desirable to at least partly improve certain aspects of known methods of manufacturing an image sensor comprising a layer of microlenses.

### BRIEF SUMMARY

An embodiment overcomes all or part of the disadvantages of known image sensors.

An embodiment provides a method of manufacturing an electronic circuit comprising the following steps, in the order:
a) forming of an opening in a semiconductor substrate comprising a first surface and a second surface opposite to the first surface, the opening extending from the first surface to the second surface, and forming of at least one electrically-conductive pad comprising a first portion extending over the first surface and a second portion covering the flanks of the opening and delimiting a gap in the opening;
b) deposition of a first layer made of a first resin, the first resin being non-photosensitive, the first layer made of the first resin covering the electrically-conductive pad and filling the gap, and crosslinking of the first layer made of the first resin;
c) chemical etching by plasma of the first layer made of the first resin to delimit a first block of the first resin in the gap; and
d) deposition of a first protection layer on the first block.

According to an embodiment, the first surface comprises a recess in which is located the first portion, a groove being present between the first portion and the flank of the recess, the first layer made of the first resin filling the groove at step b), and a second block made of the first resin being further delimited in the groove at step c).

According to an embodiment, the method further comprises, after step d), the following steps in the order:
e) forming of a plurality of microlenses in a second layer made of the first resin and covering the first protection layer, where the plurality of microlenses does not cover said at least one electrically-conductive pad; and
f) deposition of a second protection layer on the plurality of microlenses and on the first protection layer around the plurality of microlenses.

According to an embodiment, the forming of the plurality of microlenses comprises the following steps in the order:
g) deposition of the second layer made of the first resin covering the first protection layer;
h) forming of a mask made of a second resin, on top of and in contact with the second layer made of the first resin;
i) forming of structures in the form of microlenses in the mask; and
j) transfer of said structures into the second layer made of the first resin by physical etching to form the plurality of microlenses in the second layer.

According to an embodiment, after step j), the mask is removed by means of a solvent.

According to an embodiment, the method further comprises, after step f), the following step:
k) removal of the first protection layer and of the second protection layer from at least part of the first portion, while keeping the first protection layer and the second protection layer on the first block.

According to an embodiment, the method comprises, at step k), the removal of the first protection layer and of the second protection layer from at least part of the first portion while keeping the first protection layer and the second protection layer on the second block.

According to an embodiment, the method comprises, prior to step a), the forming of a plurality of photodetectors in the semiconductor substrate.

According to an embodiment, the plasma comprises oxygen.

According to an embodiment, the first protection layer is made of an oxide, for example of silicon oxynitride (SiON).

According to an embodiment, step b) successively comprises the deposition of a first sub-layer of the first resin having a first viscosity, the crosslinking of the resin of the first sub-layer, the deposition of a second sub-layer of the first resin having a second viscosity on the first sub-layer, and the crosslinking of the first resin of the second sub-layer.

According to an embodiment, the first viscosity is lower than the second viscosity, the first viscosity being in the range from 1 mPa·s to 30 mPa·s, and the second viscosity being in the range from 30 mPa·s to 150 mPa·s.

An embodiment also provides an electronic circuit comprising:

a semiconductor substrate comprising a first surface, a second surface opposite to the first surface, and an opening extending from the first surface to the second surface;

an electrically-conductive pad comprising a first portion extending over the first surface and a second portion covering the flanks of the opening and delimiting a gap in the opening;

a first block made of a first resin in the gap, the first resin being non-photosensitive, the first block made of the first resin being crosslinked; and

a first protection layer covering the first block.

According to an embodiment, the electronic circuit further comprises:

a plurality of photodetectors inside and on top of the semiconductor substrate;

a plurality of microlenses made of the first resin and covering the first protection layer, where the plurality of microlenses does not cover said at least one electrically-conductive pad; and

a second protection layer over the plurality of microlenses and over the first protection layer around the plurality of microlenses.

According to an embodiment, the first surface comprises a recess in which is located the first portion, a groove being present between the first portion and the flank of the recess, the electronic circuit comprising a second block of the first resin in the groove, the first protection layer covering the second block.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1, FIG. 2, FIG. 3, FIG. 4, FIG. 5, FIG. 6, FIG. 7, FIG. 8, FIG. 9, FIG. 10, FIG. 11, FIG. 12, and FIG. 13 are cross-section views illustrating a device obtained at the end of successive steps of an embodiment of an image sensor manufacturing method; and

FIG. 14 is an image obtained by scanning electron microscopy illustrating another embodiment of an image sensor.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the forming of the photodetectors of the described image sensors, as well as of their control circuits, has not been detailed, the forming of these elements being within the abilities of those skilled in the art based on the indications of the present disclosure.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%. Further, it is here considered that the terms “insulating” and “conductive” respectively signify “electrically-insulating” and “electrically-conductive”.

A method of manufacturing an electronic circuit corresponding to an image sensor will now be described. Generally, this embodiment of a manufacturing method is implemented for any type of electronic circuit comprising contact pads, in which case the steps concerning elements specific to an image sensor are not implemented.

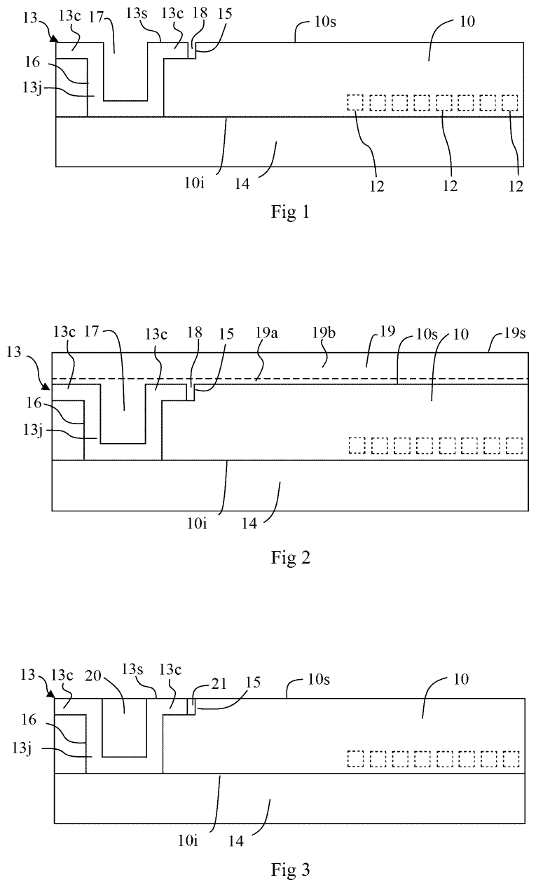

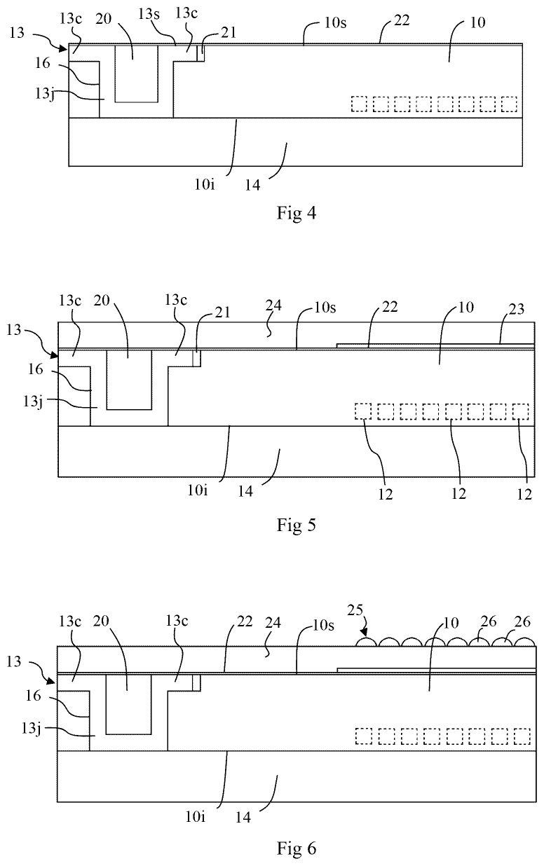

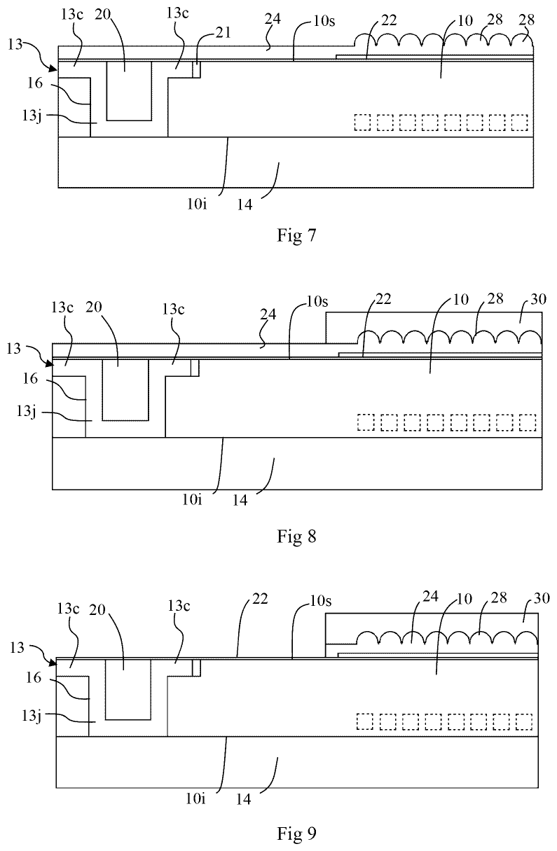

FIGS. 1 to 13 illustrate, schematically and partially, devices or structures obtained at the end of successive steps of an embodiment of an image sensor manufacturing method.

More particularly, FIG. 1 corresponds to an initial structure comprising a semiconductor substrate 10, for example a silicon substrate, in which photodetectors 12 have been previously formed. As an example, photodetectors 12 are photodiodes, for example, adapted to capturing an infrared, visible, and/or ultraviolet radiation. As an example, photodetectors 12 are photodetectors made in CMOS (Complementary Metal Oxide Semiconductor) technology.

Substrate 10 comprises an upper surface 10s and a lower surface 10i, opposite to upper surface 10s. Substrate 10 is covered, on the side of the upper surface 10s, by one or a plurality of elements, not shown in the drawings, for example a dielectric protection layer, colored filters covering photodetectors 12, an opaque screen covering areas of substrate 10 comprising no photodetector 12, etc. Substrate 10 is covered, on the side of lower surface 10i, with an interconnection structure 14, comprising a stack of insulating layers having conductive tracks, not shown, extending between them, and having conductive vias, not shown, extending therethrough. According to an embodiment, substrate 10 has a thickness in the range from 3 μm to 10 μm.

In this example, substrate 10 is intended to be illuminated through its upper surface 10s. The initial structure further comprises one or a plurality of contact pads 13, a single contact pad 13 being shown in FIG. 1. According to an embodiment, contact pad 13 is electrically insulated from substrate 10 by at least one insulating layer, not shown. Pads 13 are arranged out of line with photodetectors 12 so as not to mask photodetectors 12. As an example, in top view, photodetectors 12 are located in a central region of substrate 10, and pads 13 are located in front of a peripheral region of substrate 10.

Each contact pad 13 comprises a contact area 13c which extends in a recess 15 provided in the upper surface 10s of substrate 10. The contact area 13c of each pad 13 is intended to be connected to an external device, for example by means of an electrically-conductive wire, for example a metal wire. Contact area 13c comprises an upper surface 13s. Substrate 10 comprises, for each contact pad 13, a through opening 16 which extends from upper surface 10s to lower surface 10i. Opening 16 emerges into recess 15. According to an embodiment, opening 16 has a substantially constant cross-section, when viewed in a direction perpendicular to surface 10s. As an example, the cross-section of opening 16 is square or rectangular, in particular inscribed within a rectangle having its short side length varying from 2 μm to 10 μm and having its long side length varying from 5 μm to 100 μm. Contact pad 13 comprises a junction portion 13j which extends in through opening 16. As an example, the junction portion 13j of contact pad 13 is connected to one or a plurality of metallization levels of the interconnection structure 14 arranged on the side of the lower surface 10i of substrate 10. As an example, contact pads 13 are made of a metallic material, for example of aluminum. Junction portion 13j covers the flanks of opening 16. However, opening 16 is not completely filled by junction portion 13j, so that an air-filled gap 17, emerging onto the outside, remains in opening 16. As an example, junction portion 13j has a thickness, measured with respect to the flanks of opening 16, which is in the range from 200 nm to 2 μm, and is for example equal to approximately 2 μm. As an example, the depth of gap 17 is in the range from 3 μm to 10 μm, and is for example equal to approximately 6 μm. As an example, the thickness of contact area 13c is equal to the thickness of junction portion 13j. As an example, the depth of recess 15 is substantially equal to the thickness of contact area 13c and is in the range from 200 nm to 2 μm.

As an example, contact pads 13 can be used for the exchange of signals with the image sensor and/or for the power supply of the image sensor. According to another example, one of contact pads 13 can form part of a protection structure such as a seal ring, in which case the pad extends along the entire periphery of the image sensor.

According to an embodiment, upper surface 10s is planar outside of recesses 15 and of through openings 16. An air-filled groove 18 is present in recess 15 between the flank of recess 15 and contact pad 13.

FIGS. 2 to 4 illustrate devices obtained at the end of steps of planarization of the structure of FIG. 1 to obtain a substantially planar face on the side of the upper surface 10s of substrate 10.

FIG. 2 illustrates a device obtained at the end of a step of forming of a resin layer 19 on the upper surface 10s of substrate 10.

Layer 19 is, for example, deposited all over the upper surface 10s of substrate 10, for example, by spin coating. Layer 19 thus covers contact pads 13 and photodetectors 12. Resin layer 19 particularly fills, for each contact pad 13, gap 17 and groove 18 when the latter is present. Layer 19 for example has, outside of areas where it covers contact pads 13, a thickness in the range from 1 μm to 6 μm, for example in the order of 4 μm. According to an embodiment, layer 19 has a substantially planar upper surface 19s.

The resin of layer 19 is, for example, a crosslinked resin which cannot be dissolved in usual liquid solvents for developing and/or etching resins. The resin of layer 19 is, for example, a non-photosensitive resin. As an example, the resin of layer 19 is selected so that it can be crosslinked, for example by UVs or from a certain temperature, for example, in the order of 200° C. As an example, the resin of layer 19 is selected so that it can be etched by reactive ion bombardment, also known as RIE (Reactive ion etching), using a plasma, for example based on oxygen. As an example, the resin of layer 19 comprises a polymer, for example of acrylic or polyhydroxystyrene type.

Advantageously, the viscosity of the resin forming layer 19 is selected so as to obtain a complete filling, for each contact pad 13, of gap 17, and of groove 18 when present, and to obtain a substantially planar upper surface 19s. According to an embodiment, layer 19 is formed by a single deposition operation. According to an embodiment, the forming of layer 19 comprises the deposition of a first sub-layer 19a of the resin of layer 19 having a first viscosity, the crosslinking of the resin of first sub-layer 19a, the deposition of a second sub-layer 19b of the resin of layer 19 having a second viscosity, and the crosslinking of the resin of second sub-layer 19b. The first sub-layer allows the filling of gaps 17. The first viscosity is lower than the second viscosity. According to an embodiment, the first viscosity is in the range from 1 mPa·s to 30 mPa·s, and is for example equal to 25 mPa·s. According to an embodiment, the second viscosity is in the range from 30 mPa·s to 150 mPa·s, and is for example equal to 50 mPa·s. The first viscosity is advantageously adapted to facilitating the filling of gaps 17. The second viscosity is advantageously adapted to facilitating the obtaining of the substantially planar upper surface 19s.

FIG. 3 illustrates a device obtained at the end of a step of etching of resin layer 19 to expose the upper surface 10s of substrate 10 and the upper surface of contact pad 13. The etch step delimits a block 20 of the material forming layer 19 in the gap 17 delimited by each contact pad 13. When groove 19 is present, the etch step delimits a block 21 of the material forming layer 19 in groove 18.

According to an embodiment, the etching implemented during this step is a remote, and therefore isotropic, plasma etching (a method sometimes designated with the terms “dry-stripping” or “dry-ashing”). The chemical etching plasma used preferably comprises oxygen. As an example, the chemical etching plasma comprises oxygen, nitrogen, and hydrogen. As an example, the temperature of the material etched during this step is in the range from 80° C. to 200° C., for example in the order of 170° C. This embodiment has the advantage of being selective over the material of upper surface 10s.

According to an embodiment, the etching implemented during this step is an ion bombardment etching, a reactive dry etching, or a dry etching. Such an etching cause a removal of material by bombardment, for example, by using an oxygen-based plasma.

The above-mentioned etching is stopped when the upper surface 10s of substrate 10 or the upper surface 13s of contact pad 13 is exposed.

FIG. 4 illustrates a device obtained at the end of a step of deposition of a protection layer 22 made of an electrically-insulating material on the surface of the device shown in FIG. 3.

Layer 22 for example continuously extends over the entire upper surface of the device of FIG. 4. Thus, layer 22 covers in particular the upper surface 13s of pads 13, blocks 20, and blocks 21, and the upper surface 10s of substrate 10. Layer 22 is, for example, made of an oxide, for example of silicon oxynitride (SiON) or silicon oxide (SiO₂) deposited at low temperature, for example 150° C.

As an example, protection layer 22 is deposited by a conformal deposition method on the upper surface of the device shown in FIG. 3, for example by chemical vapor deposition, such as Plasma-Enhanced Chemical Vapor Deposition (PECVD). Layer 22 has a thickness in the range from 30 nm to 200 nm, for example in the order of 50 nm. As an example, the temperature at which the protection layer 22 is formed is in the range from 150° C. to 250° C., for example in the order of 150° C.

FIGS. 5 to 7 illustrate devices obtained at the end of steps of forming of optical filters and of a layer of microlenses on the side of the upper surface 10s of substrate 10, in front of photodetectors 12.

FIG. 5 illustrates a device obtained at the end of a step of forming of optical filters 23 on protection layer 22 and of a step of forming of a resin layer 24 on optical filters 23 and on protection layer 22 around optical filters 23.

Optical filters 23 are formed on protection layer 22 vertically in line with photodetectors 12. The optical filters comprise color filters and/or interference filters. Advantageously, protection layer 22 protects blocks 20 and 21 during the forming of optical filters 23 or during the reworking thereof.

Resin layer 24 is, for example, deposited over the entire surface of protection layer 22. Layer 24 has, for example, a thickness in the range from 1 μm to 5 μm, for example in the order of 4 μm.

According to an embodiment, the resin of layer 24 is the same as the resin of layer 19. The resin of layer 24 is, for example, a crosslinked resin which cannot be dissolved in usual liquid solvents used for developing and/or etching resins. The resin of layer 24 is, for example, a non-photosensitive resin. As an example, the resin of layer 24 is selected so that it can be crosslinked, for example by UVs or from a certain temperature, for example, in the order of 200° C. As an example, the resin of layer 24 is selected so that it can be etched by RIE, in particular by means of an oxygen-based plasma. As an example, the resin of layer 24 comprises a polymer, for example of acrylic type.

FIG. 6 illustrates a device obtained at the end of a step of forming of an etch mask 25 on the upper surface of resin layer 24. Mask 25 comprises structures in the form of microlenses, intended to be transferred into resin layer 24 during a subsequent etch step, so as to form microlenses in layer 24.

As an example, mask 25 is formed from a resist layer. The resist of mask 25 is, for example, first deposited all over the upper surface of layer 24, on top of and in contact therewith. At this stage, the resist of mask 25 has, for example, a substantially uniform thickness over the entire surface of the structure. The deposition of the resist of mask 25 can be performed by a spin-coating technique or by any other adapted deposition technique. The resist layer of mask 25 is then structured, for example by photolithography, to form, in front of photodetectors 12, separate resist pads 26. In this example, an individual resist pad 26 is provided in front of each photodetector 12 of the sensor. A flow anneal is then implemented, during which resist pads 26 are deformed to take the shape of microlenses. After the flow anneal, resist pads 26 are for example separate. The described embodiments are however not limited to this specific case. Pads 26 for example have a thickness smaller than the thickness of layer 24.

FIG. 7 illustrates a device obtained at the end of a step of physical etching of layer 24 and of mask 25, resulting in transferring the pattern of mask 25 into an upper portion of layer 24. The etching is for example stopped when all the resin of mask 25 has been consumed.

Thus, in the device illustrated in FIG. 7, layer 24 comprises microlenses 28 facing photodetectors 12. As an example, microlenses 28 have a height in the range from 0.5 μm to 3 μm. At this stage, connection pads 13 remain covered by the resin of layer 24.

Blocks 20 and 21 being made of a crosslinked, non-photosensitive resin, which may be the same resin as that used for microlenses 28, there is advantageously no degradation of the resin of blocks 20 and 21 during the forming of optical filters 23 and of microlenses 28.

FIGS. 8 to 13 illustrate devices obtained at the end of step of removal of the resin of resin layer 24 facing pads 13, to allow the taking of an electrical contact on pads 13.

FIG. 8 illustrates a device obtained at the end of a step of forming of a masking layer 30 made of resin on the upper surface of layer 24.

As an example, layer 30 is first deposited all over the upper surface of layer 24, for example in contact with the upper surface of layer 24. Layer 30 is then removed, for example by photolithography, in front of pads 13, so as to expose the portion of resin layer 24 coating pads 13. The resin of layer 30 is, for example, a resist. As an example, layer 30 has a thickness greater than the maximum thickness of layer 24. As an example, layer 30 has a thickness in the range from 4 μm to 10 μm, for example in the order of 6 μm.

FIG. 9 illustrates a device obtained at the end of a step of etching of layer 24 through layer 30. During this step, layer 30 is used as an etch mask.

More particularly, during this step, the portion of layer 24 which is not covered by layer 30 is removed to expose protection layer 22. Protection layer 22 can play the role of an etch stop layer.

According to an embodiment, the etching implemented during this step is a remote plasma etching (a method sometimes designated with the terms “dry-stripping” or “dry-ashing”). This chemical etching is based on the use of free radicals generated by remote plasmas. This etching technique is currently used to remove, recycle, or fully strip resin layers. This technique is further sometimes used to perform chemical treatments all over the exposed materials. It is here provided to use it, in uncommon fashion, to perform a local etching of resin layer 24 through the mask formed by resin layer 30. This technique has the advantage of being less aggressive than a physical etching, and generates no fibers or filaments based on etching products and on carbon on the flanks of layer 24.

The etching plasma used preferably comprises oxygen. As an example, the chemical etching plasma comprises oxygen, nitrogen, and hydrogen. As an example, the temperature of the material etched during this step is in the range from 80° C. to 200° C., for example in the order of 170° C.

According to an embodiment, the etching implemented during this step is an etching by ion bombardment, a reactive dry etching, or a dry etching. Such an etching results in a removal of material by bombardment, for example, by using an oxygen-based plasma. The plasma used during this etch step has, for example, a different composition than the plasma used during the etching resulting in the forming of microlenses 28. During the above-mentioned step, layers 30 and 24 are simultaneously consumed.

The above-mentioned etching is stopped when protection layer 22 is exposed. At this stage, a portion of layer 30 remains at the surface of layer 24 in front of microlenses 28.

FIG. 10 illustrates a device obtained at the end of a step of removal of the remaining portion of layer 30 to expose the upper surface of microlenses 28. This removal step is for example carried out by a wet etching with a solvent, by means of an etching solution enabling to selectively etch the material of layer 30 over the material of layer 24.

FIG. 11 illustrates a device obtained at the end of a step of deposition of a protection layer 32 made of an electrically-insulating material at the surface of the device illustrated in FIG. 10.

Layer 32 for example continuously extends over the entire upper surface of the device of FIG. 10. Thus, layer 32 particularly covers the microlenses 28 of layer 24 and on protection layer 22, particularly on pads 13. As an example, layer 32 is made of a material which enables to protect layer 24 from humidity. Layer 32 is for example made of an oxide, for example, of silicon oxynitride (SiON) or an oxide deposited at low temperature, for example, 150° C. According to an embodiment, layer 32 is made of the same material as layer 22.

As an example, protection layer 32 is deposited by a conformal deposition method on the upper surface of the device illustrated in FIG. 10, for example by chemical vapor deposition, for example a plasma-enhanced chemical vapor deposition (PECVD). Layer 32 for example has a thickness in the range from 50 nm to 500 nm, for example in the order of 150 nm. Advantageously, the method of forming layer 32 is the same as that used for the forming of layer 22.

FIGS. 12 to 13 illustrate devices obtained at the end of steps of local removal of protection layers 22 and 32 in front of each of contact recovery pads 13, to enable the taking of an electrical contact on pads 13.

FIG. 12 illustrates a device obtained at the end of a step of deposition of a resin layer 33 on the upper surface of the device of FIG. 11, and of forming, in resin layer 33, of through openings 34 exposing, for each contact pad 13, a portion of protection layer 32 covering the contact area 13c of contact pad 13 (as an example, the portion of contact area 13c on the left-hand side of junction portion 13j in FIG. 12). Openings 34 are for example formed by photolithography.

FIG. 13 illustrates a device obtained at the end of a step of etching of protection layer 32 and of protection layer 22 in the openings 34 of resin layer 33, which is used as an etch mask, followed by a step of removal of resin layer 33. An opening 35 is then formed in protection layer 32 and in protection layer 22, in line with each opening 34, which exposes a portion of the contact area 13c of contact pad 13. According to an embodiment, the removal of resin layer 33 can be achieved by the same etching method as that previously described in relation with FIG. 9 for the etching of layer 24. Protection layer 32 enables to protect microlenses 28 and resin blocks 20 and 21 during the etching of resin layer 33.

Resin block 20 is kept in gap 17 and resin block 21 is kept in groove 18. This advantageously enables to obtain a relatively planar upper surface, or at least having low relief amplitudes, above the junction portion 13j of each contact pad 13 and above the groove 18 surrounding each contact pad 13.

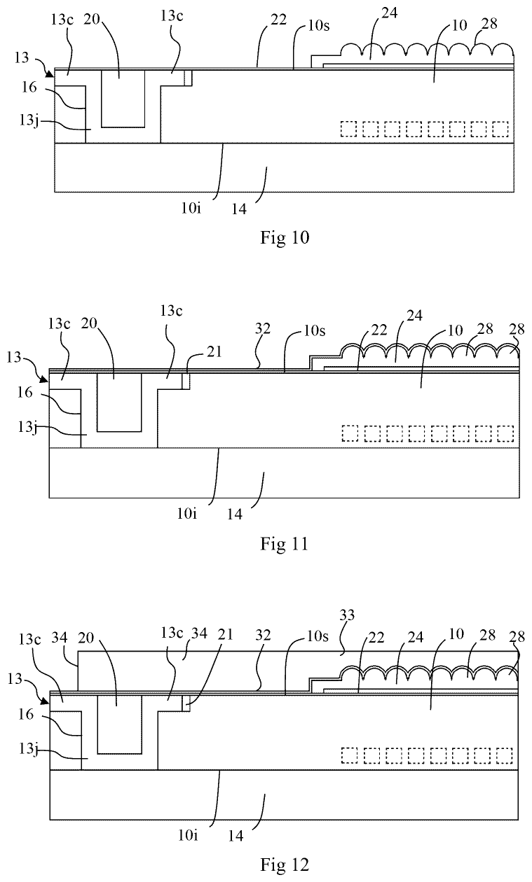

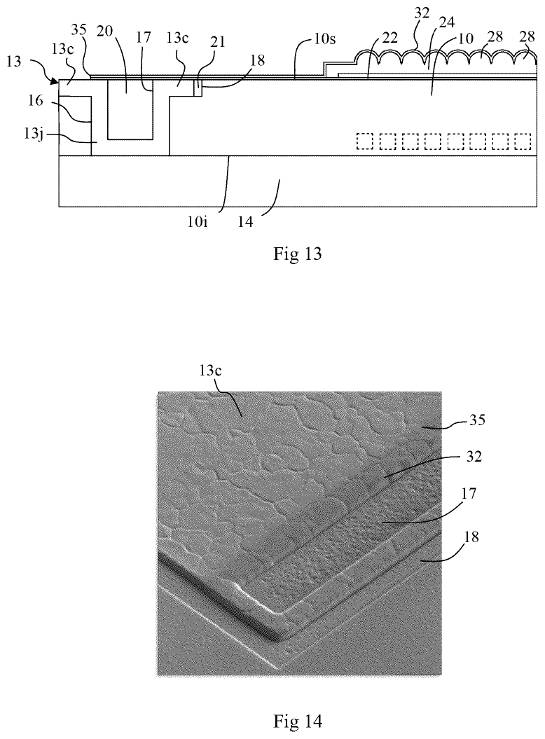

FIG. 14 is an image obtained by scanning electron microscopy of the electronic circuit of FIG. 13, gap 17 being substantially totally filled by resin block 20, not directly visible in FIG. 14, covered by protection layer 32, and groove 18 being substantially completely filled by resin block 21, not directly visible in FIG. 14.

In the embodiments previously described in relation with FIGS. 1 to 14, the contact area 13c of each contact pad 13 is housed in a recess 15 formed in the upper surface 10s of substrate 10 so that the upper surface of contact area 13c is substantially coplanar with the upper surface 10s of substrate 10. As a variant, the contact area 13c of each contact pad 13 may rest on the upper surface 10s of substrate 10, which is substantially planar, so that contact area 13c is raised with respect to the upper surface 10s of substrate 10.

An advantage of the above-described embodiments is that, after the forming of blocks 20 and 21 and of protection layer 22, the obtained upper surface of the device is substantially planar, or in any case has raised areas of low amplitude. The implementation of the subsequent steps of the image sensor manufacturing method is advantageously simpler. In particular, the forming of layer 24 having a substantially constant thickness is simpler, which enables to avoid a striation phenomenon (that is, a long-distance periodic disturbance in the spreading of the resin during its method of deposition by centrifugation) of the resin(s) present above the photodetector array, at least in the area where microlenses 28 are formed.

An advantage is that the resin used to form resin blocks 20 and 21 can be the same as the resin used for the forming of microlens layer 28. The methods of manufacturing, manipulation, crosslinking, and etching of this resin are thus advantageously well controlled.

In the above-described embodiments, protection layer 22 is shown in direct mechanical contact with contact pad 13. As a variant, contact pad 13 may be covered with a dielectric layer, for example a silicon oxide layer, deposited before the deposition of resin layer 19. In this case, during the forming of protection layer 22 on contact pad 13, protection layer 22 comes into direct mechanical contact with the dielectric layer on contact area 13c, block 20 being interposed between the dielectric layer and the portion of protection layer 22 which covers block 20.

Various embodiments and variants have been described. Those skilled in the art will understand that certain features of these various embodiments and variants may be combined, and other variants will occur to those skilled in the art. In particular, the described embodiments are not limited to the above-mentioned examples of dimensions and of materials.

Finally, the practical implementation of the described embodiments and variants is within the abilities of those skilled in the art based on the functional indications given hereabove.

Electronic circuit manufacturing method includes the following steps, in the order: a) forming of an opening (16) in a semiconductor substrate (10) including a first surface (10s) and a second surface (10i) opposite to the first surface (10s), the opening (16) extending from the first surface (10s) to the second surface (10i), and forming of at least one electrically-conductive pad (13) including a first portion (13c) extending over the first surface (10s) and a second portion (13j) covering the flanks of the opening (16) and delimiting a gap (17) in the opening (16); b) deposition of a first layer (19) made of a first resin, the first resin being non-photosensitive, the first layer (19) made of the first resin covering the electrically-conductive pad (13) and filling the gap (17), and crosslinking of the first layer (19) made of the first resin; c) chemical etching by plasma of the first layer (19) made of the first resin to delimit a first block (20) of the first resin in the gap (17); and d) deposition of a first protection layer (22) on the first block (20).

The first surface (10s) includes a recess (15) in which is located the first portion (13c), a groove (18) being present between the first portion (13c) and the flank of the recess (15), the first layer (19) made of the first resin filling the groove (18) at step b), and a second block (21) of the first resin being further delimited in the groove (18) at step c).

Method further includes, after step d), the following steps in the order: c) forming of a plurality of microlenses (28) in a second layer (24) made of the first resin and covering the first protection layer (22), where the plurality of microlenses (28) does not cover said at least one electrically-conductive pad (13); and f) deposition of a second protection layer (32) on the plurality of microlenses (28) and on the first protection layer (22) around the plurality of microlenses (28).

The forming of the plurality of microlenses (28) includes the following steps in the order: g) deposition of the second layer (24) made of the first resin covering the first protection layer (22); h) forming of a mask (25) made of a second resin, on top of and in contact with the second layer (24) made of the first resin; i) forming of structures (26) in the form of microlenses in the mask (25); and j) transfer of said structures (26) into the second layer (24) made of the first resin by physical etching to form the plurality of microlenses (28) in the second layer (24).

After step j), the mask (25) is removed by means of a solvent.

Method further includes, after step f), the following step: k) removal of the first protection layer (22) and of the second protection layer (32) from at least part of the first portion (13c), while keeping the first protection layer (22) and the second protection layer (32) on the first block (20).

Method includes, at step k), the removal of the first protection layer (22) and of the second protection layer (32) from at least part of the first portion (13c) while keeping the first protection layer (22) and of the second protection layer (32) on the second block (21).

Method includes, prior to step a), the forming of a plurality of photodetectors (12) in the semiconductor substrate (10).

The plasma includes oxygen.

The first protection layer (22) is made of an oxide, for example of silicon oxynitride (SiON).

Step b) successively includes the deposition of a first sub-layer (19a) of the first resin having a first viscosity, the crosslinking of the resin of the first sub-layer (19a), the deposition of a second sub-layer (19b) of the first resin having a second viscosity on the first sub-layer (19a), and the crosslinking of the first resin of the second sub-layer (19b).

The first viscosity is lower than the second viscosity, the first viscosity being in the range from 1 mPa·s to 30 mPa·s, and the second viscosity being in the range from 30 mPa·s to 150 mPa·s.

Electronic circuit including: a semiconductor substrate (10) including a first surface (10s), a second surface (10i) opposite to the first surface (10s), and an opening (16) extending from the first surface (10s) to the second surface (10i); an electrically conductive pad (13) including a first portion (13c) extending over the first surface (10s) and a second portion (13j) covering the flanks of the opening (16) and delimiting a gap (17) in the opening (16); a first block (20) made of a first resin in the gap (17), the first resin being non-photosensitive, the first block (20) made of the first resin being crosslinked; and a first protection layer (22) covering the first block (20).

Electronic circuit further includes: a plurality of photodetectors (12) inside and on top of the semiconductor substrate (10); a plurality of microlenses (28) made of the first resin and covering the first protection layer (22), where the plurality of microlenses (28) does not cover said at least one electrically-conductive pad (13); and a second protection layer (32) on the plurality of microlenses (28) and on the first protection layer (22) around the plurality of microlenses (28).

The first surface (10s) includes a recess (15) in which is located the first portion (13c), a groove (18) being present between the first portion (13c) and the flank of the recess (15), the electronic circuit including a second block (21) of the first resin in the groove (18), the first protection layer (22) covering the second block (21).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming an opening in a semiconductor substrate, the semiconductor substrate including a first surface and a second surface opposite to the first surface, the opening positioned between the first surface and the second surface and forming an electrically-conductive pad, the electrically-conductive pad including a first portion positioned over the first surface and a second portion covering flanks of the opening and delimiting a gap in the opening;
depositing a first layer covering the electrically-conductive pad and filling the gap, the first layer containing a first resin, the first resin being non-photosensitive;
crosslinking the first resin in the first layer;
chemically etching, using a plasma, the first layer to delimit a first block containing the first resin in the gap; and
depositing a first protection layer on the first block.

2. The method according to claim 1, wherein the first surface includes a recess, the recess forming a groove between the first portion and the first surface of the semiconductor substrate, wherein the first layer containing the first resin is deposited in the groove, delimiting a second block of the first resin in the groove.

3. The method according to claim 1, further comprising:
forming a plurality of microlenses in a second layer,
wherein the second layer contains the first resin and covers the first protection layer, and
wherein the plurality of microlenses does not cover the electrically-conductive pad; and
depositing a second protection layer on the plurality of microlenses and on the first protection layer.

4. The method according to claim 3, wherein forming the plurality of microlenses further comprises:
depositing the second layer covering the first protection layer;
forming a mask on top of and in contact with the second layer, the mask containing a second resin;
forming structures in the form of the plurality of microlenses in the mask; and
transferring the structures into the second layer by physical etching to form the plurality of microlenses in the second layer.

5. The method according to claim 4, wherein the mask is removed using a solvent.

6. The method according to claim 3, further comprising:
removing the first protection layer and the second protection layer from a part of the first portion, the first protection layer and the second protection layer covering the first block.

7. The method according to claim 6, further comprising:
removing the first protection layer and the second protection layer from a part of the first portion, the first protection layer and the second protection layer covering the second block.

8. The method according to claim 1, wherein the semiconductor substrate contains a plurality of photodetectors.

9. The method according to claim 1, wherein the plasma contains oxygen.

10. The method according to claim 1, wherein the first protection layer includes an oxide.

11. The method according to claim 1, wherein depositing the first layer further comprises:
depositing a first sub-layer containing the first resin covering the electrically-conductive pad and filling the gap, the first sub-layer having a first viscosity;
crosslinking the first resin of the first sub-layer;
depositing a second sub-layer containing the first resin covering the first sub-layer, the second sub-layer having a second viscosity; and
crosslinking the first resin of the second sub-layer.

12. The method according to claim 11, wherein the first viscosity is lower than the second viscosity, the first viscosity being in the range from 1 mPa·s to 30 mPa·s, and the second viscosity being in the range from 30 mPa·s to 150 mPa·s.

13. An electronic circuit, comprising:
a semiconductor substrate, including a first surface, a second surface opposite to the first surface, and an opening positioned between the first surface and the second surface;
an electrically conductive pad, including a first portion positioned over the first surface and a second portion covering flanks of the opening and delimiting a gap in the opening;
a first block containing a first resin in the gap in the opening, the first resin being non-photosensitive and the first resin in the first block being crosslinked; and
a first protection layer covering the first block.

14. The electronic circuit according to claim 13, further comprising:
a plurality of photodetectors inside and on top of the semiconductor substrate;
a plurality of microlenses containing the first resin covering the first protection layer, the plurality of microlenses not covering the electrically-conductive pad; and
a second protection layer covering the plurality of microlenses and covering the first protection layer.

15. The electronic circuit according to claim 13, wherein the first surface includes a recess, the recess forming a groove positioned between the first portion and the first surface of the semiconductor substrate, wherein depositing the first layer forms a second block containing the first resin in the groove, the second block being covered by the first protection layer.

16. A method, comprising:
forming an opening in a semiconductor substrate, the semiconductor substrate including a first surface, a second surface opposite the first surface, and a recess in the first surface, the opening positioned between the first surface and the second surface, the semiconductor substrate further including a plurality of photodetectors, the opening being out of line with the plurality of photodetectors;
forming an electrically-conductive pad in the opening, the electrically-conductive pad including a first portion positioned over a part of the recess forming a groove between the electrically-conductive pad and the first surface of the semiconductor substrate, the electrically-conductive pad further including a second portion positioned over the second surface of the semiconductor structure and delimiting a gap in the opening;
depositing a first layer containing a first resin over the electrically-conductive pad and the semiconductor substrate, the first layer filling the gap and the groove;
etching the first layer exposing the first portion and the first surface of the semiconductor substrate, and delimiting a first block containing the first resin in the gap and a second block containing the first resin in the groove;
depositing a first protection layer over the electrically-conductive pad and the semiconductor substrate;
depositing a second layer containing the first resin over the first protection layer;
forming a first mask over a part of the second layer, the mask containing microlens structures, the microlens structures aligned over the plurality of photodetectors;
physically etching the first mask and the second layer, transferring the microlens structures into the second layer over the plurality of photodetectors;
forming a second mask over the microlens structures in the second layer; and
etching the second layer not covered by the second mask, exposing the first protection layer.

17. The method according to claim 16, further comprising:
removing the second mask, exposing the microlens structures;
forming a second protection layer over the first protection layer and the microlens structures;
forming a third mask over the microlens structures; and
etching the second protection layer and the first protection layer not covered by the third mask, exposing a part of the first portion of the electrically-conductive pad.

18. The method according to claim 16, wherein an interconnection structure is arranged below the second surface, the second portion of the electrically-conductive pad positioned over the interconnection structure.

19. The method according to claim 16, wherein forming the first mask over the part of the second layer further comprises:
depositing the first mask over the second layer;
forming resist pads aligned over the plurality of photodetectors using photolithography; and
annealing the resist pads to form the microlens structures.

20. The method according to claim 16, wherein the first protection layer and the second protection layer include an oxide.
